(19) United States
(12) Patent Application Publication
(10) Pub. No.: US 2015/0332789 A1
(43) Pub. Date: Nov. 19, 2015

(54) SEMICONDUCTOR MEMORY DEVICE PERFORMING SELF-REPAIR OPERATION

(71) Applicant: SK hynix Inc., Icheon-si (KR)

(72) Inventors: Seung-Min Lee, Seoul (KR); Won-Ha Choi, Icheon-si (KR)

(21) Appl. No.: 14/510,645

(22) Filed: Oct. 9, 2014

(30) Foreign Application Priority Data
May 14, 2014 (KR) 10-2014-0058087

(51) Int. Cl. G11C 29/44; G11C 29/52

(52) U.S. Cl. CPC G11C 29/4401; G11C 29/52

(57) ABSTRACT

A semiconductor memory device includes a memory cell array including a main cell array and a repair cell array, a command controller that controls an input/output operation of the memory cell array, an address generator that stores a repair address, and generates an internal address according to an external address requested to be read or written, an ECC that performs a parity operation for data input/output to the memory cell array, an address table that associates an address, at which a fail has occurred when the fail has occurred in the ECC, with a number of times of occurrence of the fail, and a repair controller that selects a repair address according to the number of times of the occurrence of the fail stored in the address table, and controls the address generator to allow information of the selected repair address to be stored.

The present application claims priority under 35 U.S.C. §119(a) to Korean application number 10-2014-0058087, filed on May 14, 2014, in the Korean Intellectual Property Office, which is incorporated herein by reference in its entirety as set forth in full.

### BACKGROUND

1. Technical Field

The invention relates to a semiconductor memory device. Particularly, the invention relates to a semiconductor memory device that performs a repair operation by itself without an instruction of a memory controller.

2. Related Art

In a semiconductor memory device, a memory controller determines whether a cell fails, performs an operation for cutting an internal fuse when a repair command for the cell having failed is provided, and repairs the cell having failed with a redundant cell.

As the cell size of a semiconductor memory device is reduced, a bit error rate is increased. Therefore, it is necessary to provide a semiconductor memory device capable of lowering a bit error rate while reducing the load of a controller.

### SUMMARY

In an embodiment of the invention, a semiconductor memory device includes. a memory cell array including a main cell array and a repair cell array. The semiconductor memory device also includes a command controller that controls an input/output operation of the memory cell array according to a read or write request. Further, the semiconductor memory device includes an address generator that stores a repair address, and generates an internal address according to an external address requested to be read or written. In addition, the semiconductor memory device includes an ECC that performs a parity operation for data input/output to the memory cell array. The semiconductor memory device also includes an address table that associates an address, at which a fail has occurred when the fail has occurred in the ECC, with a number of times of occurrence of the fail, and stores the associated address and the number of times of the occurrence of the fail. The semiconductor memory device also includes and a repair controller that selects a repair address according to the number of times of the occurrence of the fail stored in the address table, and controls the address generator to allow information of the selected repair address to be stored.

In an embodiment of the invention, a semiconductor memory device, in which a logic die and a plurality of cell dies are stacked, wherein each of the plurality of cell dies include a memory cell array including a main cell array and a repair cell array. Each of the plurality of cell dies also include an address generator that stores a repair address, and generates a second internal address according to a first internal address provided from the logic die and the repair address. The logic die includes a command controller that controls an input/output operation of the memory cell array according to a read or write request. The logic die also includes a main address decoder that generates the first internal address according to an external address requested to be read or written. Further, the logic die includes an ECC that performs a parity operation for data input/output to the memory cell array. In addition, the logic die includes an address table that associates an address, at which a fail has occurred when the fail has occurred in the ECC, with a number of times of occurrence of the fail, and stores the associated address and the number of times of the occurrence of the fail. The logic die also includes a repair controller that selects a repair address according to the number of times of the occurrence of the fail stored in the address table, and controls the address generator such that information of the selected repair address is stored.

In an embodiment of the invention, a memory system includes a semiconductor memory device including a memory cell array including a main cell array and a repair cell array. The semiconductor memory device may also include a command controller that controls an input/output operation of the memory cell array according to a read or write request. In addition, the semiconductor memory device may also include an address generator that stores a repair address, and generates an internal address according to an external address requested to be read or written and the repair address. The semiconductor memory device may also include an ECC that performs a parity operation for data input/output to the memory cell array. Further, the semiconductor memory device may include an address table that associates an address, at which a fail has occurred when the fail has occurred in the ECC, with a number of times of occurrence of the fail, and stores the associated address and the number of times of the occurrence of the fail. Moreover, the semiconductor memory device includes a repair controller that selects a repair address according to the number of times of the occurrence of the fail stored in the address table, and controls the address generator such that information of the selected repair address is stored. The memory system also includes a memory controller that controls the semiconductor memory device.

In an embodiment of the invention, a method for operating a semiconductor memory device includes a first step of reading data and a parity from a memory cell array corresponding to an address requested to be read. The method includes a second step of performing a parity operation for the data and the parity. In addition, the method includes a third step of associating the address requested to be read with a number of times of occurrence of a fail when the fail has occurred as a result of the parity operation, and storing the associated address and the number of times of the occurrence of the fail. The method also includes a fourth step of repairing the address requested to be read when the number of times of the occurrence of the fail exceeds a critical point.

### BRIEF DESCRIPTION OF THE DRAWINGS

FIG. 1 is a block diagram of a semiconductor memory device according to an embodiment of the invention;

FIG. 2 is a block diagram of a semiconductor memory device according to an embodiment of the invention;

FIG. 3 is a block diagram of a semiconductor memory device according to an embodiment of the invention;

FIG. 4 is a flowchart illustrating a read operation of a semiconductor memory device according to an embodiment of the invention; and

FIG. 5 is a flowchart illustrating a mask write operation of a semiconductor memory device according to an embodiment of the invention.

### DETAILED DESCRIPTION

Hereinafter, a semiconductor memory device according to the invention will be described in detail with reference to the accompanying drawings through an embodiment. A semiconductor memory device that performs a repair operation by itself without a repair command of a memory controller is described. A semiconductor memory device according to the invention performs a repair operation by itself without a command of a memory controller, thereby reducing the load of the controller and simultaneously lowering a bit error rate.

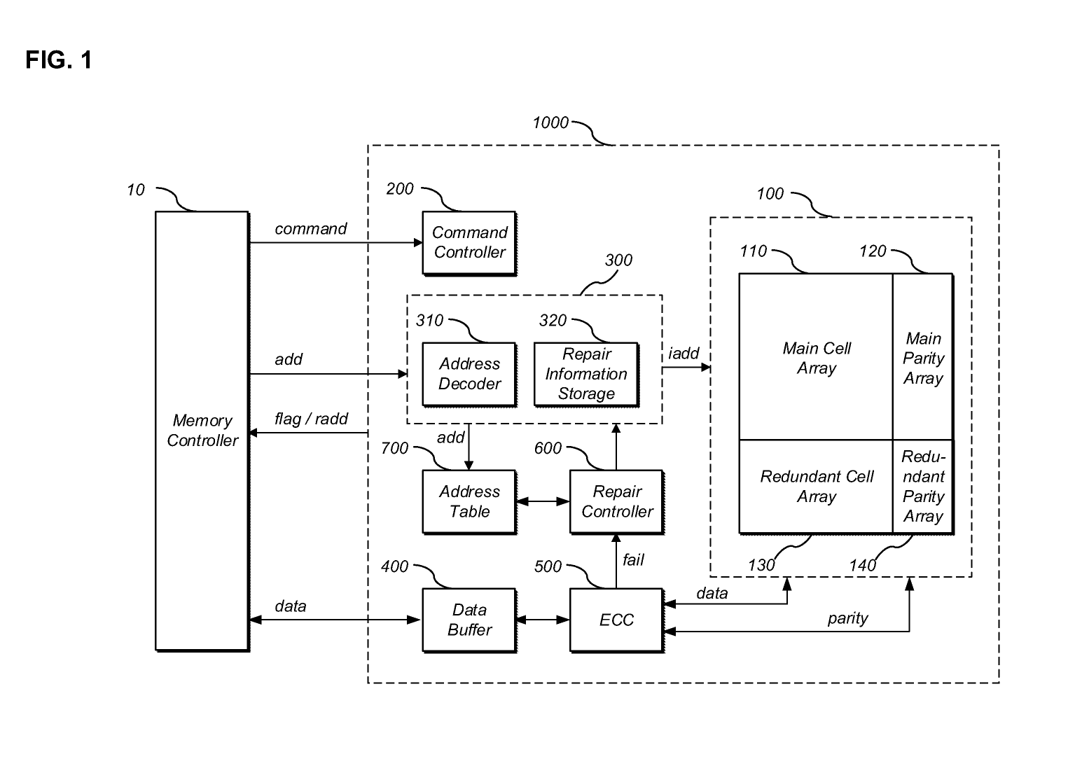

Referring to FIG. 1, a block diagram of a semiconductor memory device 1000 according to an embodiment of the invention is shown.

The semiconductor memory device 1000 includes a memory cell array 100 including a main cell array 110, a main parity array 120 that stores parity information corresponding to the main cell array 110, a redundant cell array 130, and a redundant parity array 140 that stores parity information corresponding to the redundant cell array 130.

The semiconductor memory device 1000 includes a command controller 200 that receives a command from a memory controller 10 and controls a read operation, a write operation and the like. The semiconductor memory device 1000 also includes an address generator 300 that receives an external address add from the memory controller 10 and generates an internal address iadd. Further, the semiconductor memory device 1000 includes a data buffer 400 that transmits/receives data to/from the memory controller 10. Since the operations of the command controller 200 and the data buffer 400 are general, a detailed description will be omitted.

The address generator 300 includes an address decoder 310 that decodes the external address add to generate the internal address iadd. The address generator 300 also includes a repair information storage 320 that stores information of a repaired address.

The repair information storage 320 may determine whether the external address add is a repaired address. When the external address add is determined as the repaired address, the address decoder 310 generates an internal address iadd corresponding to the redundant cell array 130 other than the main cell array 110. The repair information storage 320 may be implemented using an E-fuse array that may be electrically blown.

The semiconductor memory device 1000 includes an ECC 500. The ECC 500 performs a parity operation from data and a parity output from the memory cell array 100 in a read operation, and determines whether a fail has occurred.

Furthermore, in a write operation, the ECC 500 generates a parity for data provided from the memory controller 10. The ECC 500 also provides the data and the parity to the memory cell array 100.

The semiconductor memory device 1000 includes a repair controller 600. When the ECC 500 determines that the fail has occurred as a result of the parity operation, the repair controller 600 associates an address, at which the fail has occurred, with the number of times of the occurrence of the fail at the address. Further, the repair controller 600 stores the associated address and number of times in an address table 700. In an embodiment, the address stored in the address table 700 is the external address add.

The fail output from the ECC 500 may be corrected as a soft fail, or may not be corrected as a hard fail.

In the case of the soft fail, the repair controller 600 updates the number of times of the occurrence of the fail in the address table 700. When the updated number of times of the occurrence of the fail exceeds a critical point, a repair operation for a corresponding address may be immediately started. In the alternative, the repair operation, for example, may also be delayed to a predetermined time point as with an idle state.

In the case of the hard fail, the repair controller 600 may set the number of times of the occurrence of fail, which corresponds to a corresponding address in the address table 700, as a value exceeding the critical value, delay the repair operation to the predetermined time point, or immediately start the repair operation for the corresponding address.

The repair operation is an operation, in which the repair controller 600 stores an external address to be repaired in the repair information storage 320. The repair operation also corresponds to an operation to provide a control signal such that an E-fuse array is blown in the case of the E-fuse array.

In the invention, the repair operation may be independently performed in the semiconductor memory device 1000 without an instruction of the memory controller 10.

As described above, the time point, at which the repair operation is performed, may be changed according to various embodiments.

For example, the repair operation may be performed when the semiconductor memory device 1000 is in an idle state. In the idle state, the repair controller 600 determines that an external address, at which the number of times of the occurrence of fail exceeds the critical point among external addresses stored in the address table 700. Further, the repair controller 600 stores the corresponding external address in the repair information storage 320.

When a hard fail is found or when the number of times of the occurrence of fail is updated in the address table 700 and the updated number of times exceeds the critical point, the repair operation may also be immediately performed for a corresponding address.

The semiconductor memory device 1000 may provide the memory controller 10 with a flag activated while the repair operation is being performed. Furthermore, the semiconductor memory device 1000 may provide the memory controller 10 with an external address at which the repair is executed. Consequently, the memory controller 10 can delay scheduling for a bank, which includes the address at which repair is executed, until the repair is ended.

After the external address is repaired, when the number of times of the occurrence of fail at the corresponding external address exceeds the critical point again, the external address may be additionally repaired. Such an additional repair operation may be performed through an operation to associate an external address, at which fail has occurred, with a new internal address instead of an existing internal address.

In a write operation, the address generator 300 generates the internal address iadd with reference to the input external address add and the stored repair address. In addition, data requested to be written is stored in the main cell array 110 or the redundant cell array 130. In the write operation, the ECC 500 does not determine whether fails have occurred. Further, the repair controller 600 does not update the address table 700.

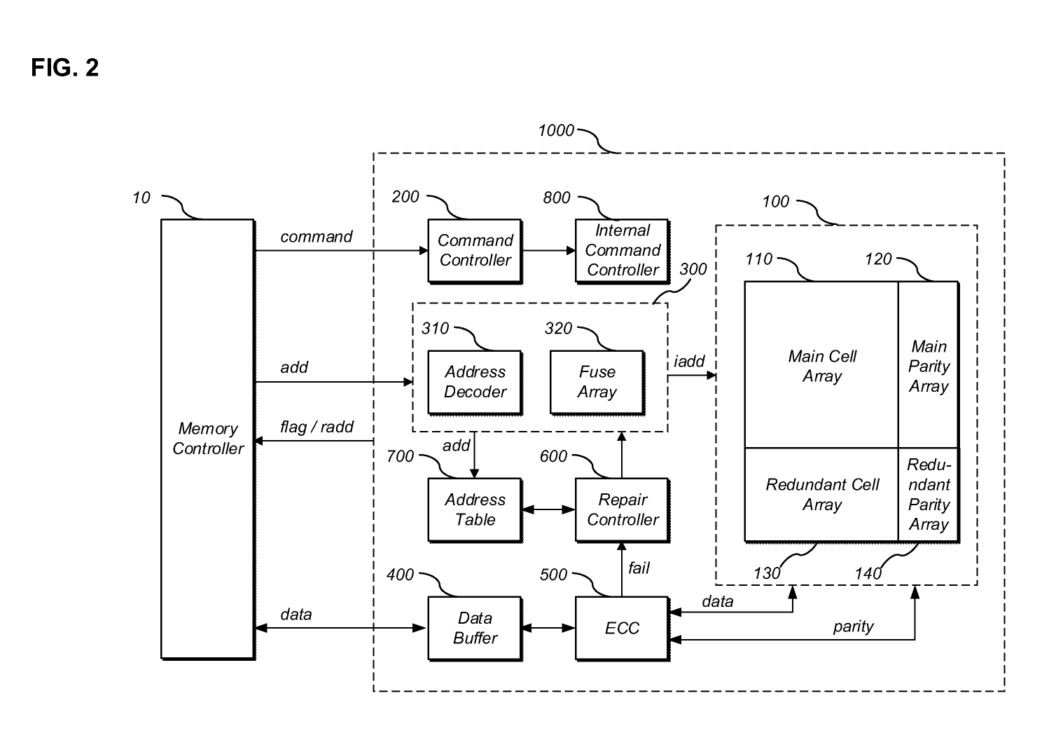

Referring to FIG. 2, a block diagram of a semiconductor memory device 1000 according to an embodiment of the invention is shown.

The semiconductor memory device 1000 of FIG. 2 further includes an internal command controller 800. The internal command controller 800 may control a mask write operation (masked write).

For example, when the memory cell array 100 has a data width of M bytes, the mask write operation is performed in order to write only data of N bytes of the M bytes (M and N are natural numbers, and N<M).

In this case, since data of M-N bytes is stored as is and only the data of N bytes is corrected, an internal read operation to read the data of M bytes is performed in advance.

When a mask write command is provided from the memory controller 10, the command controller 200 controls the internal command controller 800 such that the internal read operation is performed.

The internal read operation is a read operation for the data of M bytes including the data of N bytes for which the mask write operation is to be performed. The internal read operation is also substantially the same as the read operation described with reference to FIG. 1.

In the internal read operation, the ECC 500 performs a parity operation from output data of M bytes and a parity corresponding to the output data of M bytes. In addition, the repair controller 600 updates the address table 700 according to whether fail has occurred.

In the internal read operation, the data of M-N bytes, except for the N bytes to be subject to the mask write among the data output from the memory cell array 100, is temporarily stored in the data buffer 400 or the ECC 500.

When the internal read operation is ended, the internal command controller 800 controls an internal write operation.

The internal write operation is an operation to write the temporarily stored data of M-N bytes and the data of the total M bytes, which includes the N bytes requested to be written, in the memory cell array 100.

The ECC 500 performs a parity operation for the data of the total M bytes and generates a new parity corresponding to the data. The data of the M bytes and the parity are stored in the memory cell array 100.

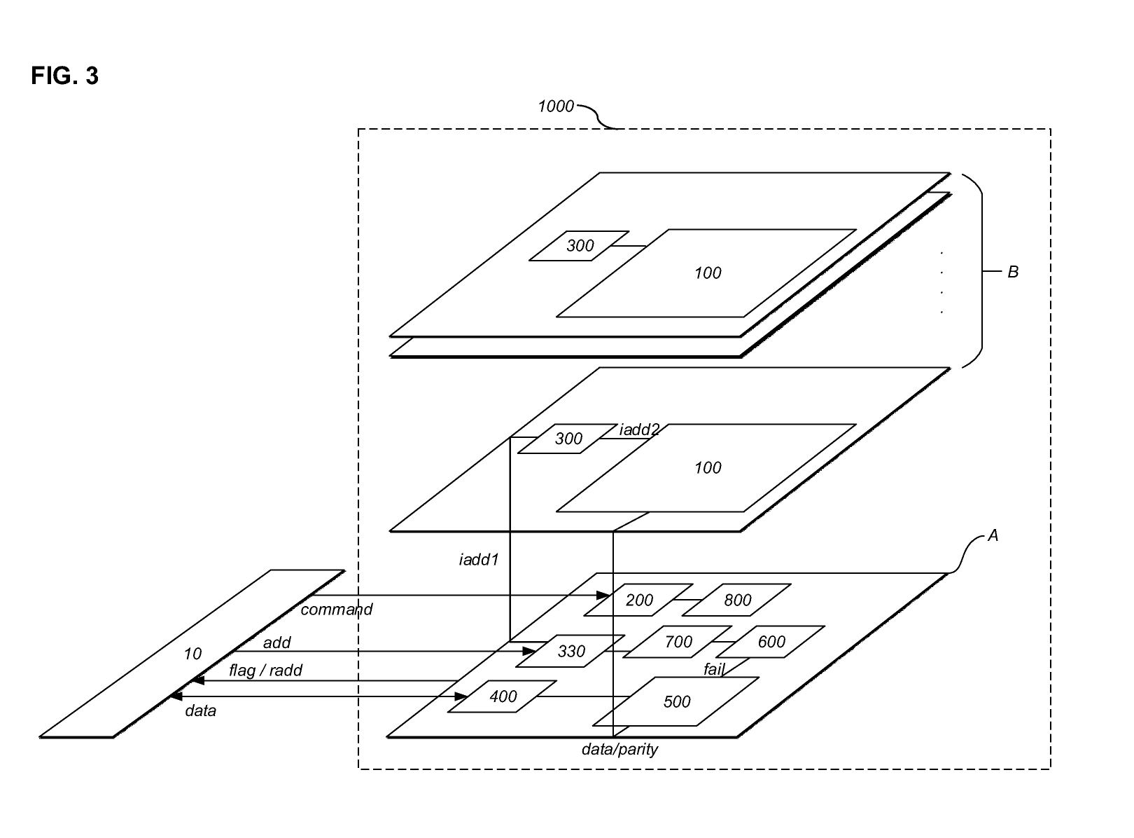

Referring to FIG. 3, a block diagram of a semiconductor memory device according to an embodiment of the invention is shown.

The semiconductor memory device 1000 of FIG. 3 has a stack structure of a logic die A and a plurality of cell dies B.

Each of the plurality of cell dies B may include the memory cell array 100 and the address generator 300. In addition, the logic die A may include the other blocks except for the memory cell array 100 and the address generator 300.

The logic die A may further include a main address decoder 330 that primarily decodes the external address add and generates a first internal address iadd1 that is provided to each die. The first internal address iadd1 is provided to each cell die B. Further, the address generator 300 included in each cell die decodes the first internal address iadd1 with reference to a repair address stored therein and outputs a second internal address iadd2.

The relation between the first internal address iadd1 and the second internal address iadd2 may be understood to be the same as the relation between the external address add and the internal address iadd in FIG. 1 and FIG. 2.

The logic die A and the cell die B may exchange a data signal, a control signal and the like through a through electrode (TSV). FIG. 3 does not illustrate a through electrode for various control signals and simplifies and illustrates a through electrode for only an address and a data signal.

In a read operation, when data and a parity are output from the cell die B, the ECC 500 determines whether a fail has occurred. When the fail has occurred, the repair controller 600 updates the number of times of the occurrence of fail corresponding to a first internal address iadd1, at which the fail has occurred, in the address table 700.

The repair controller 600 controls a repair operation with respect to a first internal address iadd1, at which the number of times of the occurrence of fail exceeds the critical point, or a first internal address iadd1 at which hard fail has occurred.

In the repair operation, the repair controller 600 finds a cell die corresponding to a first internal address iadd1 to be repaired. The repair controller 600 also stores, as a repair address, the first internal address iadd1 in the repair information storage 320 of the address generator 300 included in the cell die. When the repair information storage 320 includes an E-fuse array, the repair controller 600 provides a control signal to blow the fuse such that the corresponding first internal address iadd1 is stored as a repair address.

Since the semiconductor memory device 1000 of FIG. 3 is substantially the same as the semiconductor memory devices described in FIG. 1 and FIG. 2 except for the stack structure, a detailed description will be omitted in order to avoid redundancy.

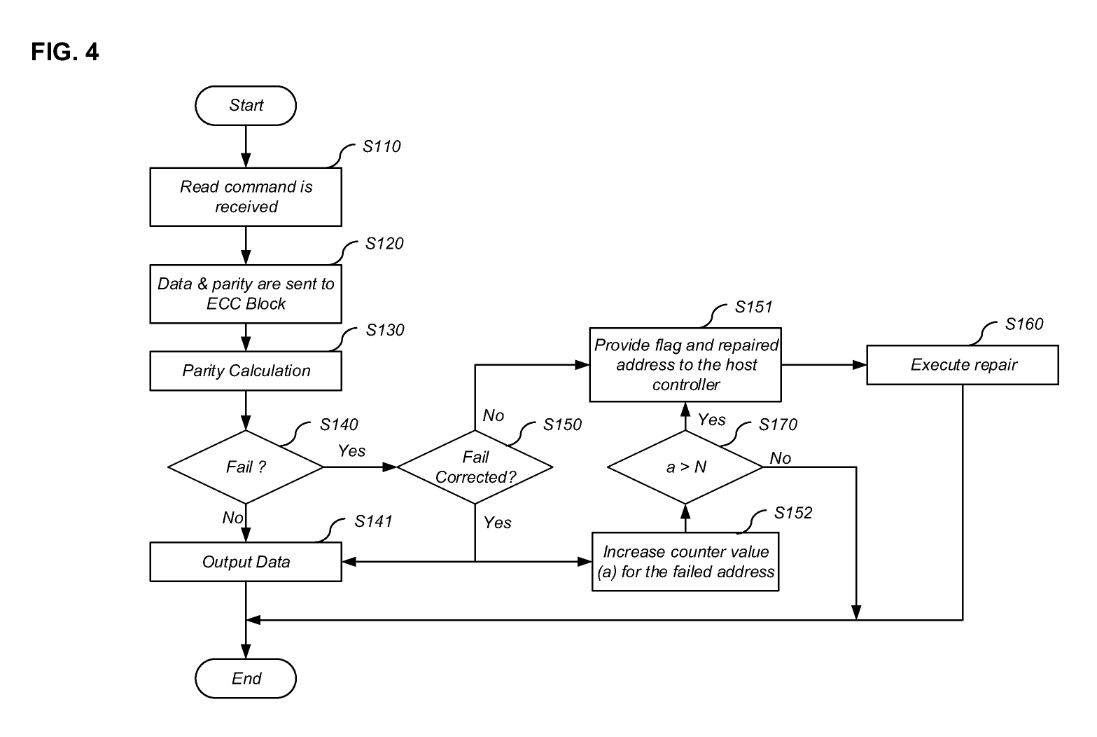

Referring to FIG. 4, a flowchart illustrating the read operation of the semiconductor memory device according to the invention is shown.

When a read command is received (S110), the semiconductor memory device 1000 performs the read operation, outputs data and a parity from the memory cell array 100, and provides the data and the parity to the ECC 500 (S120).

The ECC 500 performs a parity operation (S130) and determines whether a fail exists (S140).

When the fail does not exist, data is output (S141) and the procedure is ended.

When the fail exists, it is determined whether the fail may be corrected (S150).

When the fail is corrected as with a soft fail, corrected data is output (S141) and simultaneously the number a of times of the occurrence of the fail at an external address in the address table 700 is increased (S152).

When the number a of times of the occurrence of the fail exceeds a critical point N (see step S170) or when uncorrected fail occurs as with the hard fail in step S150, the procedure proceeds to step S151 and a repair operation is started.

In step S151, a flag to start the repair operation and an address, at which the repair is executed, are provided to the memory controller 10. Consequently, the memory controller 10 can lower a scheduling priority for a bank, which includes an address at which the repair is executed, until the repair is ended.

Then, the repair controller 600 stores a repair address in the repair information storage 320 of the address generator 300, thereby executing the repair (S160). As described above, the repair information storage 320 may include an E-fuse array. In this case, the repair controller 600 generates a control signal to blow the E-fuse array in correspondence with an external address to be repaired.

When the repair operation is ended, the flag provided to the memory controller 10 may be inactivated.

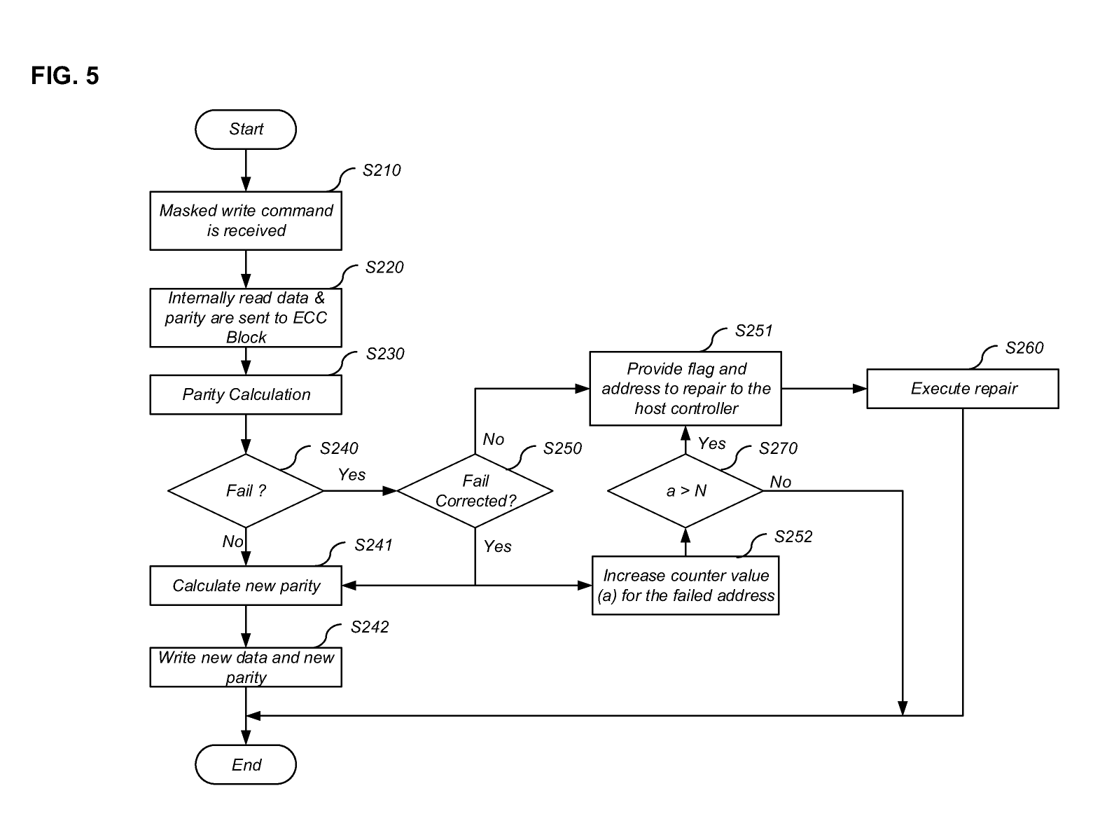

Referring to FIG. 5, a flowchart illustrating the mask write operation of the semiconductor memory device according to the invention is shown.

When a mask write command is received (S210), the semiconductor memory device 1000 performs the internal read operation, outputs data and a parity from the memory cell array 100, and provides the data and the parity to the ECC 500 (S220).

The ECC 500 performs a parity operation (S230) and determines whether a fail exists (S240).

When the fail does not exist, new data is generated from data requested to be written and data provided through internal reading, a new parity is operated using the new data (S241), the new data and the new parity are written in the memory cell array 100 (S242), and the procedure is ended.

When the fail exists, it is determined whether the fail may be corrected (S250).

When the fail is corrected as with a soft fail, step S241 and step S242 are performed using corrected data and simultaneously the number a of times of the occurrence of fail at an external address in the address table 700 is increased (S252).

When the number a of times of the occurrence of the fail exceeds the critical point N (see step S270) or when uncorrected fail occurs as with hard fail in step S250, the procedure then proceeds to step S251 and a repair operation is started.

In step S251, a flag to start the repair operation and an address, at which the repair is executed, are provided to the memory controller 10. Consequently, the memory controller 10 can lower a scheduling priority for a bank, which includes an address at which the repair is executed, until the repair is ended.

Then, the repair controller 600 programs the repair information storage 320 of the address generator 300, and thereby executes the repair (S260). As described above, the repair information storage 320 may include an E-fuse array. In this case, the repair controller 600 generates a control signal to blow the E-fuse array in correspondence with an external address to be repaired.

When the repair operation is ended, the flag may be inactivated.

While certain embodiments have been described above, it will be understood to those skilled in the art that the embodiments described are by way of examples only. Accordingly, the semiconductor memory device described should not be limited based on the described embodiments. Rather, the semiconductor memory device described should only be limited in light of the claims that follow when taken in conjunction with the above description and accompanying drawings.

What is claimed is:

1. A semiconductor memory device comprising:
a memory cell array including a main cell array and a repair cell array;
a command controller that controls an input/output operation of the memory cell array according to a read or write request;
an address generator that stores a repair address, and generates an internal address according to an external address requested to be read or written;
an ECC that performs a parity operation for data input/output to the memory cell array;
an address table that associates an address, at which a fail has occurred when the fail has occurred in the ECC, with a number of times of occurrence of the fail, and stores the associated address and the number of times of the occurrence of the fail; and
a repair controller that selects a repair address according to the number of times of the occurrence of the fail stored in the address table, and controls the address generator to allow information of the selected repair address to be stored.

2. The semiconductor memory device according to claim 1, wherein the address generator comprises:
a repair information storage that stores the repair address according to a control of the repair controller; and
an address decoder that generates the internal address according to the external address requested to be read or written and the repair address.

3. The semiconductor memory device according to claim 2, wherein the repair information storage includes an E-fuse array blown in correspondence with the repair address.

4. The semiconductor memory device according to claim 3, wherein the repair controller generates a control signal to blow the E-fuse array in correspondence with the repair address.

5. The semiconductor memory device according to claim 1, wherein the address stored in the address table in association with the number of times of the occurrence of the fail and the repair address are external addresses.

6. The semiconductor memory device according to claim 1, wherein the repair controller outputs a flag activated while the repair address is being stored and the repair address.

7. The semiconductor memory device according to claim 1, further comprising:
an internal command controller that controls an internal read operation and an internal write operation in a mask write operation.

8. A semiconductor memory device, in which a logic die and a plurality of cell dies are stacked, wherein each of the plurality of cell dies comprises:
a memory cell array including a main cell array and a repair cell array; and
an address generator that stores a repair address, and generates a second internal address according to a first internal address provided from the logic die and the repair address,
wherein the logic die comprises:
a command controller that controls an input/output operation of the memory cell array according to a read or write request;
a main address decoder that generates the first internal address according to an external address requested to be read or written;
an ECC that performs a parity operation for data input/output to the memory cell array;
an address table that associates an address, at which a fail has occurred when the fail has occurred in the ECC, with a number of times of occurrence of the fail, and stores the associated address and the number of times of the occurrence of the fail; and
a repair controller that selects a repair address according to the number of times of the occurrence of the fail stored in the address table, and controls the address generator such that information of the selected repair address is stored.

9. The semiconductor memory device according to claim 8, wherein the address generator comprises:
a repair information storage that stores the repair address according to control of the repair controller; and
an address decoder that generates the second internal address according to the first internal address and the repair address.

10. The semiconductor memory device according to claim 9, wherein the repair information storage includes an E-fuse array blown in correspondence with the repair address.

11. The semiconductor memory device according to claim 10, wherein the repair controller generates a control signal to blow the E-fuse array in correspondence with the repair address.

12. The semiconductor memory device according to claim 8, wherein the address stored in the address table in association with the number of times of the occurrence of the fail, and the repair address are the first internal address.

13. The semiconductor memory device according to claim 8, wherein the repair controller outputs a flag, activated while the repair address is being stored, and the repair address.

14. The semiconductor memory device according to claim 8, wherein the logic die further comprises:
an internal command controller that controls an internal read operation and an internal write operation in a mask write operation.

15. A memory system comprising:
a semiconductor memory device including a memory cell array including a main cell array and a repair cell array, a command controller that controls an input/output operation of the memory cell array according to a read or write request, an address generator that stores a repair address, and generates an internal address according to an external address requested to be read or written and the repair address, an ECC that performs a parity operation for data input/output to the memory cell array, an address table that associates an address, at which a fail has occurred when the fail has occurred in the ECC, with a number of times of occurrence of the fail, and stores the associated address and the number of times of the occurrence of the fail, and a repair controller that selects a repair address according to the number of times of the occurrence of the fail stored in the address table, and controls the address generator such that information of the selected repair address is stored; and
a memory controller that controls the semiconductor memory device.

16. The memory system according to claim 15, wherein, in the semiconductor memory device, the repair controller outputs a flag, activated while the repair address is being stored, and the repair address, and the memory controller lowers a scheduling priority for a bank associated with the repair address while the flag is being activated.

17. A method for operating a semiconductor memory device, comprising:
a first step of reading data and a parity from a memory cell array corresponding to an address requested to be read;
a second step of performing a parity operation for the data and the parity;
a third step of associating the address requested to be read with a number of times of occurrence of fail when the fail has occurred as a result of the parity operation, and storing the associated address and the number of times of the occurrence of the fail; and
a fourth step of repairing the address requested to be read when the number of times of the occurrence of the fail exceeds a critical point.

18. The method according to claim 17, further comprising:
a fifth step of executing repair for an address, at which the fail has occurred, regardless of the number of times of the occurrence of the fail when the fail having occurred as the result of the parity operation is difficult to be repaired.

19. The method according to claim 17, further comprising:
a step of providing an activated flag and a repair address before the fourth step is performed; and
a step of deactivating the flag after the fourth step has ended.

20. The method according to claim 17, further comprising:
a step of determining whether the fail is a soft fail or a hard fail.
